(19) United States
(12) Patent Application Publication
(10) Pub. No.: US 2026/0100622 A1
(43) Pub. Date: Apr. 9, 2026

(54) ELECTRIC MOTOR WITH INTEGRATED PRINTED CIRCUIT BOARD COILS

(71) Applicant: G.W. Lisk Company, Inc., Clifton, NY (US)

(72) Inventor: Jeffery Tyler, Newark, NY (US)

(21) Appl. No.: 19/351,663

(22) Filed: Oct. 7, 2025

Related U.S. Application Data
(60) Provisional application No. 63/705,104, filed on Oct. 9, 2024.

(51) Int. Cl. H02K 11/00; H02K 1/16; H02K 1/2733; H02K 5/15; H02K 7/00; H02K 11/215; H05K 1/11; H05K 1/14; H05K 1/16

(52) U.S. Cl. CPC H02K 11/0094; H02K 1/16; H02K 1/2733; H02K 5/15; H02K 7/003; H02K 11/215; H05K 1/115; H05K 1/144; H05K 1/165; H02K 2211/03

(57) ABSTRACT

An electric motor assembly including a printed circuit board including a plurality of apertures, wherein at least three apertures of the plurality of apertures are enclosed by coils, the coils being integrated in the printed circuit board, a stator including a ring portion and a plurality of teeth extending axially from the ring portion, the plurality of teeth extending through the plurality of apertures, and a rotor arranged adjacent the plurality of teeth, the rotor including a first ring magnet, wherein the coils are arranged to generate a magnetic flux within the stator that is transferred to the rotor to generate circumferential displacement in the rotor about an axis of rotation, and the plurality of teeth extend in an axial direction arranged parallel to the axis of rotation.

### CROSS-SECTION TO RELATED APPLICATIONS

This application claims the benefit under 35 U.S. C. § 119(e) of U.S. Provisional Application No. 63/705,104, filed Oct. 9, 2024, which application is incorporated herein by reference in its entirety.

### FIELD

The present disclosure relates to motors, and more particularly, to electric motors with coils arranged in a printed circuit board.

### BACKGROUND

An electric motor is a machine that converts electrical energy into mechanical energy. Most electric motors operate through the interaction between the motor's magnetic field and electric current in a wire winding to generate force in the form of torque applied on the motor's shaft. An electric generator is mechanically identical to an electric motor, but operates in reverse, converting mechanical energy into electrical energy. Electric motors can be powered by direct current (DC) sources, such as from batteries or rectifiers, or by alternating current (AC) sources, such as a power grid, inverters or electrical generators.

### SUMMARY

The present disclosure is directed to one or more exemplary embodiments of an electric motor assembly.

In an exemplary embodiment, the electric motor assembly comprises a printed circuit board including a plurality of apertures, wherein at least three apertures of the plurality of apertures are enclosed by coils, the coils being integrated in the printed circuit board, a stator including a ring portion and a plurality of teeth extending axially from the ring portion, the plurality of teeth extending through the plurality of apertures, and a rotor arranged adjacent the plurality of teeth, the rotor comprising a first ring magnet, wherein the coils are arranged to generate a magnetic flux within the stator that is transferred to the rotor to generate circumferential displacement in the rotor about an axis of rotation, and the plurality of teeth extend in an axial direction arranged parallel to the axis of rotation.

In an exemplary embodiment, the rotor is arranged axially adjacent to the plurality of teeth and the magnetic flux is transferred axially from the stator to the rotor. In an exemplary embodiment, the rotor is arranged radially adjacent to the plurality of teeth and the magnetic flux is transferred radially from the stator to the rotor. In an exemplary embodiment, the rotor is arranged axially between the ends of the plurality of teeth.

In an exemplary embodiment, the electric motor assembly further comprises a plate non-rotatably connected to the first ring magnet. In an exemplary embodiment, the plate comprises an axial surface including plurality of fins. In an exemplary embodiment, the plurality of fins extend toward that printed circuit board.

In an exemplary embodiment, the electric motor assembly further comprises a Hall effect sensor arranged on the printed circuit board between two coils. In an exemplary embodiment, the Hall effect sensor is arranged radially inward of the plurality of teeth. In an exemplary embodiment, the Hall effect sensor is arranged radially outward of the plurality of teeth.

In an exemplary embodiment, the first ring magnet comprises a first radially inward facing surface having a first diameter, the plurality of teeth comprise a second radially inward facing surface having a second diameter, the first diameter being less than the second diameter.

In an exemplary embodiment, the rotor comprises a radially outward facing surface having a first diameter, the plurality of teeth comprise a radially inward facing surface having a second diameter, and the first diameter is greater than the second diameter. In an exemplary embodiment, the electric motor assembly further comprises a shaft non-rotatably connected to the rotor, the shaft extending through a hole in the printed circuit board. In an exemplary embodiment, the electric motor assembly further comprises a second ring magnet non-rotatably connected to the first ring magnet. In an exemplary embodiment, the second ring magnet is arranged radially inward and spaced apart from the first ring magnet.

In an exemplary embodiment, the printed circuit board comprises a plurality of layers, wherein coils on the plurality of layers are electrically connected with one or more vias. In an exemplary embodiment, the ring portion is arranged on a first axial side of the printed circuit board, and the rotor is arranged on a second axial side of the printed circuit board, opposite the first axial side. In an exemplary embodiment, the electric motor assembly further comprises a wound coil assembly arranged around at least one of the at least three apertures. In an exemplary embodiment, at least one tooth of the plurality of teeth comprises a through-hole extending therethrough in an axial direction.

The present disclosure is directed to one or more exemplary embodiments of a brushless direct current motor assembly.

In an exemplary embodiment, the brushless direct current motor assembly comprises a printed circuit board including a plurality of apertures, wherein at least three apertures of the plurality of apertures are enclosed by coils, the coils being integrated in the printed circuit board, a stator including a ring portion and a plurality of teeth extending in an axial direction from the ring portion through the plurality of apertures, and a rotor arranged adjacent the plurality of teeth, the rotor comprising a first ring magnet, wherein the coils are arranged to generate a magnetic flux within the stator that is transferred to the rotor to generate circumferential displacement in the rotor about an axis of rotation, wherein the axis of rotation is arranged parallel to the axial direction.

These and other objects, features, and advantages of the present disclosure will become readily apparent upon a review of the following detailed description of the disclosure, in view of the drawings and appended claims.

### BRIEF DESCRIPTION OF THE DRAWINGS

The accompanying drawings are incorporated herein as part of the specification. The drawings described herein illustrate embodiments of the presently disclosed subject matter and are illustrative of selected principles and teachings of the present disclosure, in which corresponding reference symbols indicate corresponding parts. However, the drawings do not illustrate all possible implementations of the presently disclosed subject matter and are not intended to limit the scope of the present disclosure in any way.

FIG. 1 is a top perspective view of an actuator assembly.

FIG. 2 is a bottom perspective cross-sectional view of the actuator assembly taken generally along line 2-2 in FIG. 1.

FIG. 3A is a top perspective view of the electric motor assembly shown in FIG. 1.

FIG. 3B is a top perspective view of the electric motor assembly shown in FIG. 1.

FIG. 3C is a top plan view of the electric motor assembly shown in FIG. 1.

FIG. 4 is a top plan view of the electric motor assembly shown in FIG. 1, with the plate removed.

FIG. 5 is a top perspective view of the electric motor assembly shown in FIG. 1, showing the flux path.

FIG. 6 is a top perspective view of the electric motor assembly shown in FIG. 1.

FIG. 7A is a top perspective view of an electric motor assembly.

FIG. 7B is a top plan view of the electric motor assembly shown in FIG. 7A.

FIG. 7C is a side perspective view of the electric motor assembly shown in FIG. 7A.

FIG. 8 is a top perspective view of the electric motor assembly shown in FIG. 7A, with the plate removed.

FIG. 9 is a top plan view of the electric motor assembly shown in FIG. 7A, with the plate removed.

FIG. 10A is a top perspective view of an electric motor assembly with the rotor removed.

FIG. 10B is a top plan view of the electric motor assembly shown in FIG. 10A.

FIG. 11 is a bottom perspective view of a plate.

FIG. 12 is a top perspective view of a printed circuit board.

FIG. 13 is a top perspective view of the printed circuit board shown in FIG. 12.

FIG. 14 is an exploded bottom perspective view of the printed circuit board shown in FIG. 12.

FIG. 15 is a top perspective view of an electric motor assembly.

FIG. 16 is a top plan view of an electric motor assembly with the rotor removed.

FIG. 17 is a top perspective view of the stator shown in FIG. 16.

FIG. 18 is a top perspective view of a stator.

FIG. 19 is a top perspective view of a stator.

FIG. 20 is a top perspective view of a stator.

FIG. 21 is a top perspective view of a stator.

FIG. 22 is a top perspective view of a stator.

FIG. 23 is a top perspective view of a stator.

FIG. 24 is a top perspective view of an electric motor assembly.

FIG. 25 is a top perspective view of an electric motor assembly.

FIG. 26 is a top perspective view of an electric motor assembly.

FIG. 27 is a top perspective view of an electric motor assembly.

### DETAILED DESCRIPTION

It is to be understood that the invention may assume various alternative orientations and step sequences, except where expressly specified to the contrary. It is also to be understood that the specific assemblies and systems illustrated in the attached drawings and described in the following specification are simply exemplary embodiments of the inventive concepts defined herein. Hence, specific dimensions, directions, or other physical characteristics relating to the embodiments disclosed are not to be considered as limiting, unless expressly stated otherwise. Also, although they may not be, like elements in various embodiments described herein may be commonly referred to with like reference numerals within this section of the application.

Furthermore, it is understood that this disclosure is not limited to the particular methodology, materials and modifications described and as such may, of course, vary. It is also understood that the terminology used herein is for the purpose of describing particular aspects only, and is not intended to limit the scope of the claims.

Unless defined otherwise, all technical and scientific terms used herein have the same meaning as commonly understood to one of ordinary skill in the art to which this disclosure pertains. It should be understood that any methods, devices or materials similar or equivalent to those described herein can be used in the practice or testing of the example embodiments.

Where used herein, the terms “first,” “second,” and so on, do not necessarily denote any ordinal, sequential, or priority relation, but are simply used to more clearly distinguish one element or set of elements from another, unless specified otherwise.

Where used herein, the term “about” when applied to a value is intended to mean within the tolerance range of the equipment used to produce the value, or, in some examples, is intended to mean plus or minus 10%, or plus or minus 5%, or plus or minus 1%, unless otherwise expressly specified.

It should be appreciated that the term “substantially” is synonymous with terms such as “nearly,” “very nearly,” “about,” “approximately,” “around,” “bordering on,” “close to,” “essentially,” “in the neighborhood of,” “in the vicinity of,” etc., and such terms may be used interchangeably as appearing in the specification and claims. It should be appreciated that the term “proximate” is synonymous with terms such as “nearby,” “close,” “adjacent,” “neighboring,” “immediate,” “adjoining,” etc., and such terms may be used interchangeably as appearing in the specification and claims. The term “substantially” is intended to mean values within ten percent of the specified value.

Where used herein, the term “exemplary” is intended to mean “an example of,” “serving as an example,” or “illustrative,” and does not denote any preference or requirement with respect to a disclosed aspect or embodiment.

It should be understood that use of “or” in the present application is with respect to a “non-exclusive” arrangement, unless stated otherwise. For example, when saying that “item x is A or B,” it is understood that this can mean one of the following: (1) item x is only one or the other of A and B; (2) item x is both A and B. Alternately stated, the word “or” is not used to define an “exclusive or” arrangement. For example, an “exclusive or” arrangement for the statement “item x is A or B” would require that x can be only one of A and B. Furthermore, as used herein, “and/or” is intended to mean a grammatical conjunction used to indicate that one or more of the elements or conditions recited may be included or occur. For example, a device comprising a first element, a second element and/or a third element, is intended to be construed as any one of the following structural arrangements: a device comprising a first element; a device comprising a second element; a device comprising a third element; a device comprising a first element and a second element; a device comprising a first element and a third element; a device comprising a first element, a second element and a third element; or a device comprising a second element and a third element.

Moreover, as used herein, the phrases “comprises at least one of” and “comprising at least one of” in combination with a system or element is intended to mean that the system or element includes one or more of the elements listed after the phrase. For example, a device comprising at least one of: a first element; a second element; and a third element, is intended to be construed as any one of the following structural arrangements: a device comprising a first element; a device comprising a second element; a device comprising a third element; a device comprising a first element and a second element; a device comprising a first element and a third element; a device comprising a first element, a second element and a third element; or a device comprising a second element and a third element. A similar interpretation is intended when the phrase “used in at least one of:”is used herein.

By “non-rotatably connected” elements, it is meant that: the elements are connected so that whenever one of the elements rotate, all of the elements rotate; and relative rotation between the elements is not possible. Radial and/or axial movement of non-rotatably connected elements with respect to each other is possible, but not required. By “rotatably connected” elements, it is meant that: the elements are rotatable with respect to each other; and whenever one element is displaced radially and/or axially, all the elements are displaced radially and/or axially.

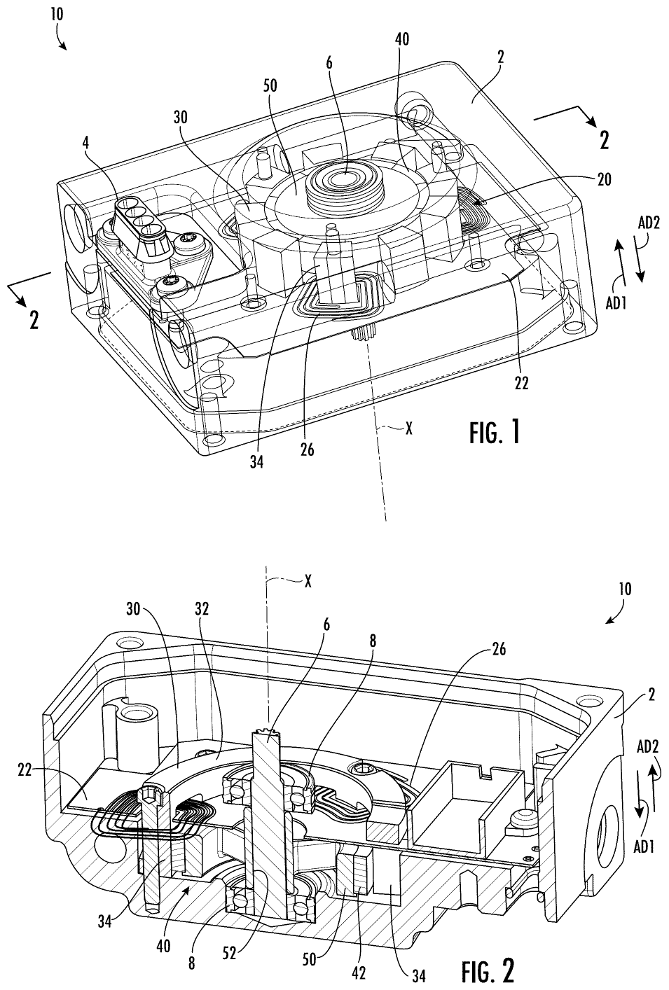

Referring now to the figures, FIG. 1 is a top perspective view of actuator assembly 10. FIG. 2 is a bottom perspective cross-sectional view of actuator assembly 10 taken generally along line 2-2 in FIG. 1. Actuator assembly 10 generally comprises electric motor assembly 20, 120. In an exemplary embodiment, actuator assembly 10 further comprises shaft 6. In an exemplary embodiment, actuator assembly 10 further comprises housing 2 and/or electrical socket 4. As shown, electric motor assembly 20, 120 is secured in housing 2. Electrical socket 4 provides an electrical conduit through housing 2 such that electric motor assembly 20, 120 can receive electrical power. Shaft 6 is non-rotatably connected to electric motor assembly 20, 120, namely, rotor 40, 140, and extends through a hole in housing 4. Shaft 6 may be further rotatably supported in housing 2 via bearings 8. In an exemplary embodiment, actuator assembly 10 and/or electric motor assembly 20, 22 is operatively arranged to drive rotation driven valves, such as butterfly valves, plug valves, etc., directly, or indirectly through an additional gear train.

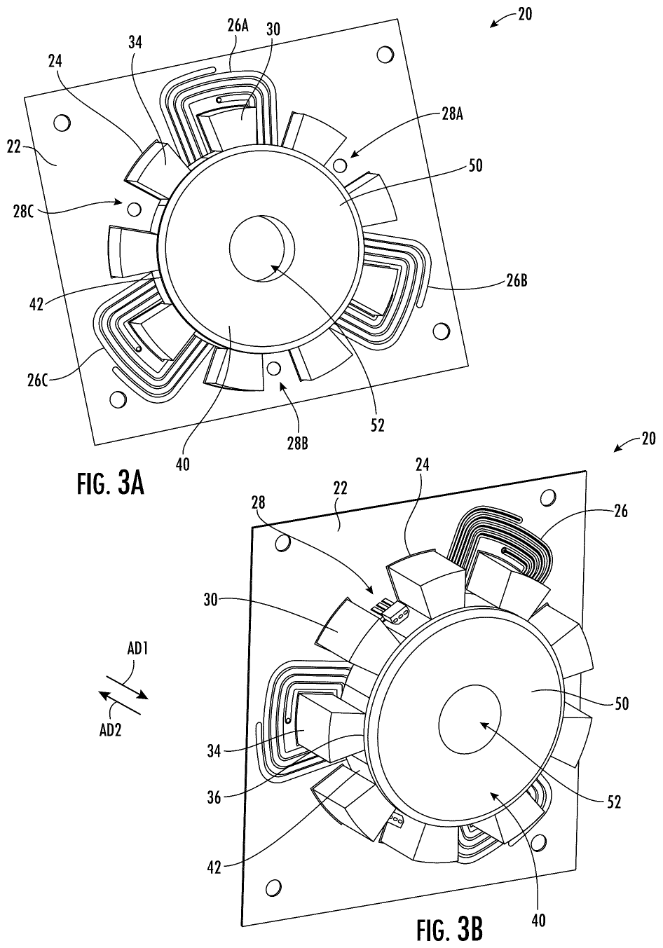

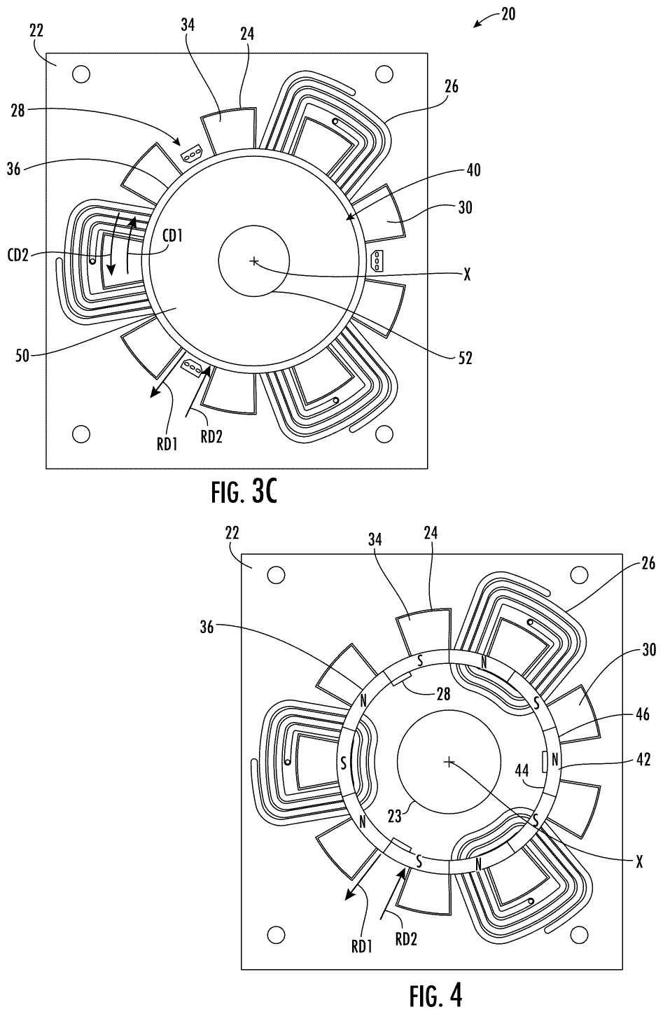

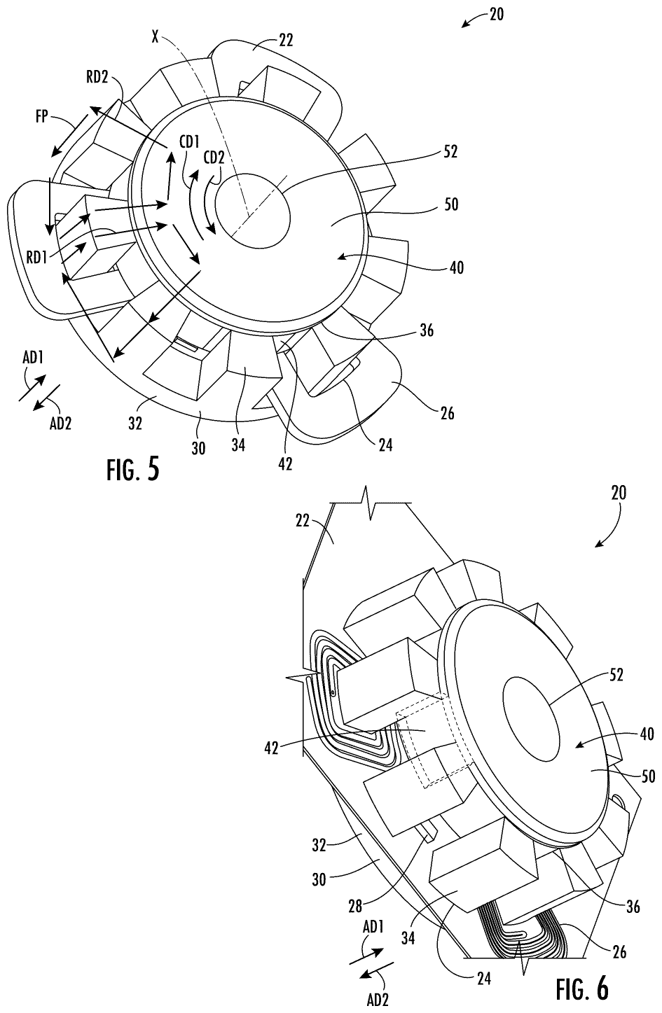

FIG. 3A is a top perspective view of electric motor assembly 20. FIG. 3B is a top perspective view of electric motor assembly 20. FIG. 3C is a top plan view of electric motor assembly 10. FIG. 4 is a top plan view of electric motor assembly 20, with plate 50 removed. FIG. 5 is a top perspective view of electric motor assembly 20 showing flux path FP, for example, of a single energized coil. FIG. 6 is a top perspective view of electric motor assembly 20. Electric motor assembly 20 comprises circuit or printed circuit board (PCB) 22, stator 30, and rotor 40. In an exemplary embodiment, electric motor assembly 20 comprises a polyphase brushless direct current (BLDC) motor.

PCB 22 comprises a plurality of through-holes 24 and one or more coils 26, for example, three coils 26A-26C. Through-holes 24 extend axially through PCB 22 and allow for teeth 34 of stator 30 to pass therethrough. In an exemplary embodiment, PCB 22 comprises nine (9) holes 24 to accommodate nine (9) stator teeth 34. In an exemplary embodiment, PCB 22 further comprises through-hole 23 through which shaft 6 extends.

Coils 26 are arranged around teeth 34 to form stator poles. For example, as shown in FIG. 3A, coil 26A is arranged around a first tooth 34, coil 26B is arranged around a second tooth 34, and coil 26C is arranged around a third tooth, wherein the first, second, and third teeth 34 are thus stator poles. Coils 26A-26C provide excitation to electric motor assembly 20 by providing a magnetic field through the stator poles that cause ring magnet 42 and thus rotor 40 to rotate. In an exemplary embodiment, coils 26A-26C are equally spaced on the stator poles extending axially from ring portion 32. In an exemplary embodiment, coils 26A-26C are arranged in the middle tooth 34 of every third tooth 34 on stator 30. It should be appreciated that the number of poles and teeth 34 are not limited to three and nine, respectively, and any suitable number of poles and teeth 34 may be used. In an exemplary embodiment, coils 26 are equally distributed about axis of rotation X every third stator tooth 34.

In an exemplary embodiment, PCB 22 further comprises one or more sensors 28 that detect rotation of rotor 40. In an exemplary embodiment, sensor 28 is a Hall effect sensor that detects rotation of ring magnet 42 (see FIGS. 3A-4 and 6). In an exemplary embodiment, and as best shown in FIG. 3A, sensors 28A-28C are arranged equidistant, for example in a circumferential and/or radial direction, about ring magnet 42.

Stator 30 comprises ring portion or yoke 32 arranged on a first axial side of PCB 22, and plurality of teeth 34 that extend axially, in axial direction AD1, through holes 24 in PCB 22 to a second axial side of PCB 22, opposite the first axial side. Teeth 34 are circumferentially spaced apart along ring portion 32. Teeth 34 that are wrapped in coils 26 are referred to as stator poles. Each of teeth 34 comprises radially inward facing surface 36 that faces and is arranged proximate to ring magnet 42 of rotor 40. In an exemplary embodiment, stator poles or teeth 34 comprise soft metal composite (SMC) material.

Rotor 40 comprises ring magnet 42. Ring magnet 42 is arranged radially inward of radially inward facing surface 36. In an exemplary embodiment, ring magnet 42 is arranged axially between the axial ends of teeth 34, as best shown in FIGS. 5-6. Ring magnet 42 is operatively arranged to displace in circumferential direction CD1, CD2 with respect to stator 30 in response to excitation of the stator poles. Ring magnet 42 is radially magnetized with alternating stator poles. In an exemplary embodiment, ring magnet 42 comprises ten (10) poles (i.e., alternating North and South poles). However it should be appreciated that ring magnet 42 is not limited to only ten (10) poles and may comprise any suitable number of poles. Ring magnet 42 comprises radially inward facing surface 44 and radially outward facing surface 46. Radially outward facing surface 46 faces and is arranged proximate to radially inward facing surface 36 of teeth 34. In an exemplary embodiment, ring magnet 42 comprises powder metal or segment assembly. For example, ring magnet 42 may be comprised of individual magnet poles or one solid magnet magnetized with multiple magnet poles.

In an exemplary embodiment, rotor 40 further comprises armature or plate 50 non-rotatably connected to ring magnet 42. Plate 50 comprises hole 52 operatively arranged to engage shaft 6. Shaft 6 is non-rotatably connected to plate 50, for example, via splines in hole 52. In an exemplary embodiment, hole 52 is a through-hole. Rotor 40 is operatively arranged to be displaced in circumferential direction CD1, CD2 about axis X, with respect to stator 30 and PCB 22. Axis X extends in axial direction AD1, AD2. Teeth 34 extend in axial direction AD1, the same as axis of rotation X.

As best shown in FIG. 5, flux path FP per coil 26 is shown. Flux path FP is created by current flowing through coil 26 and extends in axial direction AD1 through stator pole or tooth 34. Next flux path FP extends radially inward in radial direction RD1 from stator pole or tooth 34 to rotor 40, namely, magnet ring 42 and/or plate 50. Flux path FP then extends in circumferential direction CD1 and circumferential direction CD2 within rotor 40. Then flux path FP extends radially outward in radial direction RD2 from rotor 40 to teeth 34 adjacent to the stator pole tooth 34. Flux path FP extends in axial direction AD2 down the respective adjacent teeth 34 and circumferentially back to coil 26, namely in circumferential direction CD1 and circumferential direction CD2. It should be appreciated that two coils 26 can be energized at a time in a single phase (i.e., coil 26A and coil 26B, coil 26B and coil 26C, or coil 26C and coil 26A).

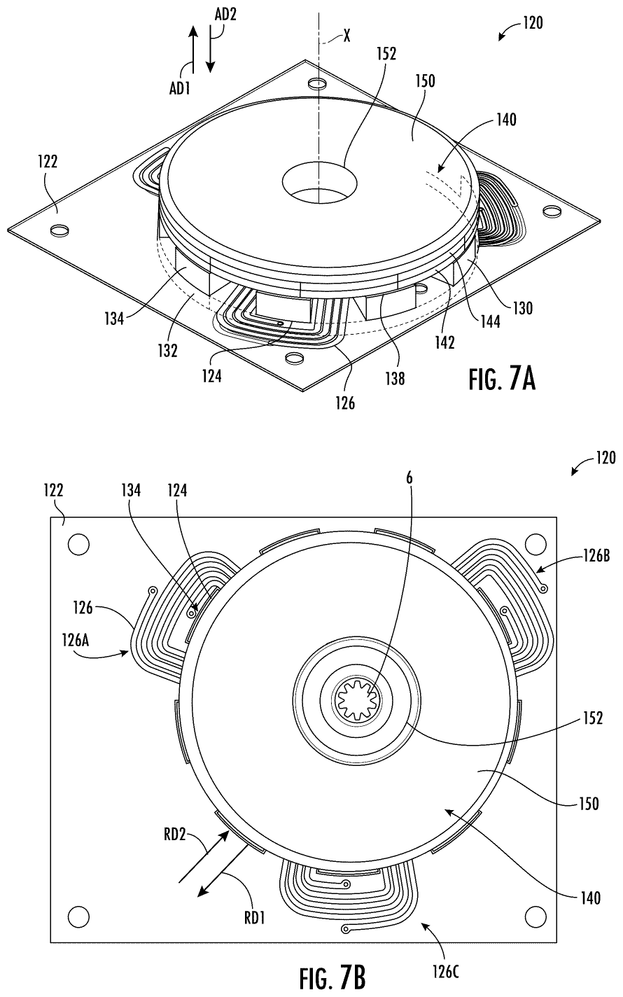

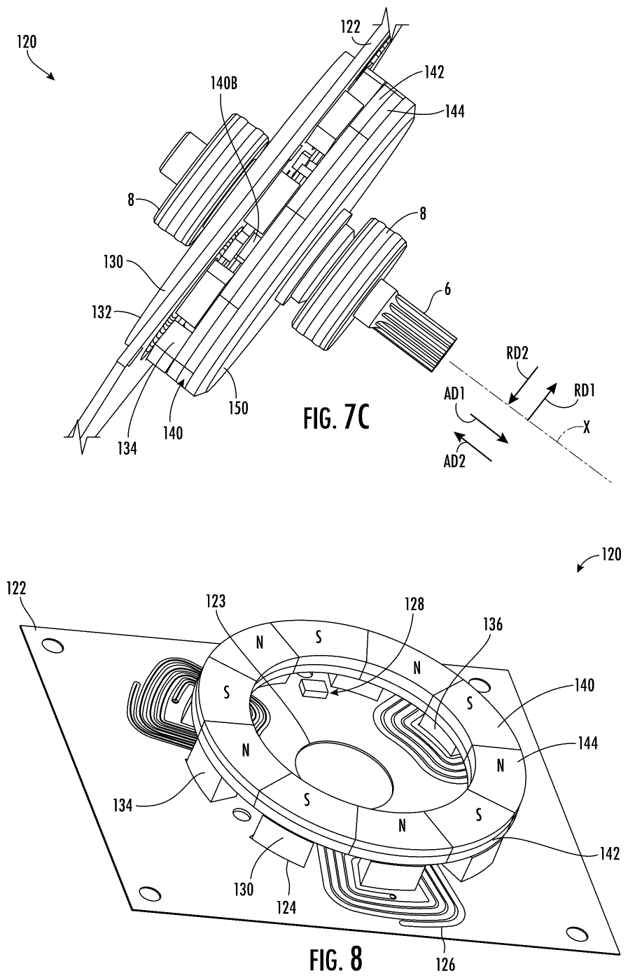

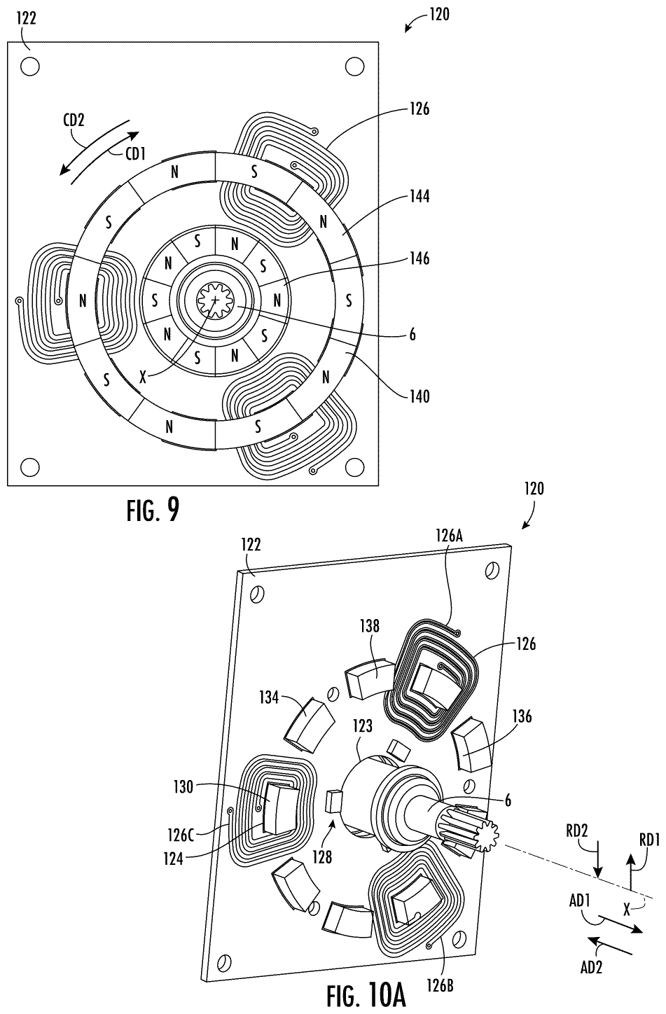

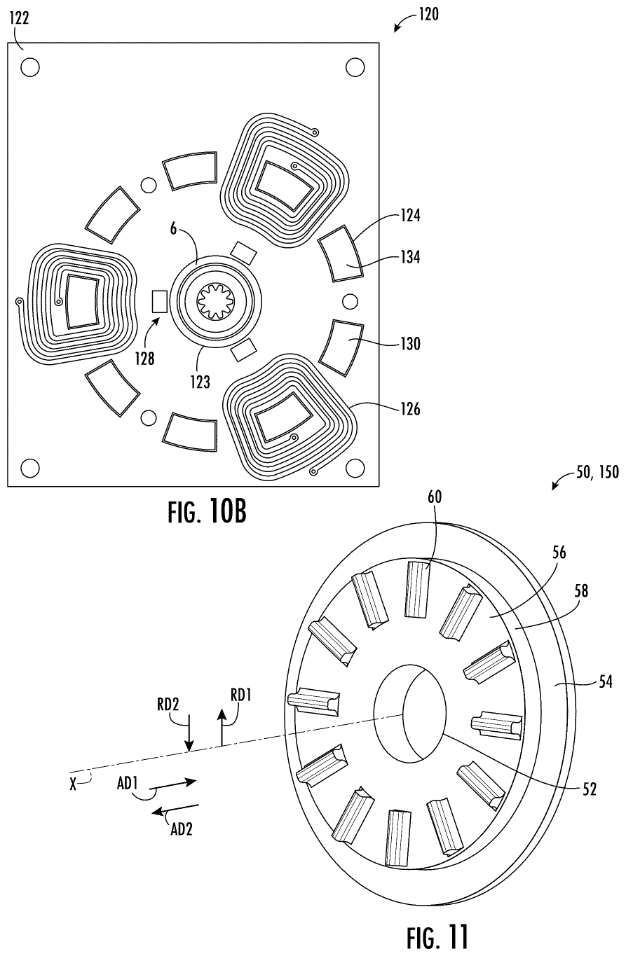

FIG. 7A is a top perspective view of electric motor assembly 120. FIG. 7B is a top plan view of electric motor assembly 120. FIG. 7C is a side perspective view of electric motor assembly 120. FIG. 8 is a top perspective view of electric motor assembly 120, with plate 150 removed. FIG. 9 is a top plan view of the electric motor assembly shown in FIG. 7A, with plate 150 removed. FIG. 10A is a top perspective view of electric motor assembly 120 with rotor 140 removed. FIG. 10B is a top plan view of electric motor assembly 120. Electric motor assembly 120 comprises PCB 122, stator 130, and rotor 140. In an exemplary embodiment, electric motor assembly 120 comprises a polyphase brushless direct current (BLDC) motor.

PCB 122 comprises a plurality of through-holes 124 and one or more coils 126, for example, three coils 126A-126C. Through-holes 124 extend axially through PCB 122 and allow for teeth 134 of stator 130 to pass therethrough. In an exemplary embodiment, PCB 122 comprises nine (9) holes 124 to accommodate nine (9) stator teeth 134. In an exemplary embodiment, PCB 122 further comprises through-hole 123 through which shaft 6 extends.

Coils 126 are arranged around teeth 134 to form stator poles. For example, as shown in FIG. 10A, coil 126A is arranged around a first tooth 134, coil 126B is arranged around a second tooth 134, and coil 126C is arranged around a third tooth, wherein the first, second, and third teeth 134 are thus stator poles. Coils 126A-126C provide excitation to electric motor assembly 120 by providing a magnetic field through the stator poles that cause ring magnet 142 and thus rotor 140 to rotate. In an exemplary embodiment, coils 126A-126C are equally spaced on the stator poles extending axially from ring portion 132. In an exemplary embodiment, coils 126A-126C are arranged in the middle tooth 134 of every third tooth 134 on stator 130. It should be appreciated that the number of poles and teeth 134 are not limited to three and nine, respectively, and any suitable number of poles and teeth 134 may be used. In an exemplary embodiment, coils 126 are equally distributed, for example circumferentially and/or radially, about axis of rotation X every third stator tooth 134.

In an exemplary embodiment, PCB 122 further comprises one or more sensors 128 that detect rotation of rotor 140. In an exemplary embodiment, sensor 128 is a Hall effect sensor that detects rotation of ring magnet 142, 146 (see FIGS. 8 and 10A-10B). In an exemplary embodiment, and as best shown in FIG. 8, sensors 128 are operatively arranged to detect rotation of ring magnet 142. For example, sensors 128 may be arranged under ring magnet 142. In an exemplary embodiment, the inner diameter of ring magnet 142 is less than the diameter of radially inward facing surface 136 such that ring magnet 142 covers sensors 128 that are mounted inboard of stator teeth 134, thereby eliminating the need for a rotation sensing magnet (i.e., ring magnet 146). In an exemplary embodiment, sensors 128 are arranged equidistant about axis X to detect rotation of ring magnet 146, which is non-rotatably connected to ring magnet 142. In an exemplary embodiment, sensors 128 are arranged equidistant about axis X to detect rotation of shaft 6. In an exemplary embodiment, sensors 128 are equally spaced in between the stator poles, 60 degrees from coils 126, radially outward of stator 130 outside diameter and ring magnet 142 outside diameter.

Stator 130 comprises ring portion or yoke 132 arranged on a first axial side of PCB 122, and plurality of teeth 134 that extend axially, in axial direction AD1, through holes 124 in PCB 122 to a second axial side of PCB 122, opposite the first axial side. Teeth 134 are circumferentially spaced apart along ring portion 132. Teeth 134 that are wrapped in coils 126 are referred to as stator poles. Each of teeth 134 comprises radially inward facing surface 136 and axial surface 138. Axial surface 138 faces and is arranged proximate to ring magnet 142 of rotor 140. In an exemplary embodiment, stator poles or teeth 134 comprise SMC material.

Rotor 140 comprises ring magnet 142. Ring magnet 142 is arranged axially adjacent to axial surface 138. Ring magnet 142 comprises a first surface facing in axial direction AD2 toward axial surfaces 138, and a second surface facing in axial direction AD1 facing away from axial surfaces 138. Ring magnet 142 is operatively arranged to displace in circumferential direction CD1, CD2 with respect to stator 130 in response to excitation of the stator poles. Ring magnet 142 is axially magnetized with alternating stator poles. In an exemplary embodiment, ring magnet 142 comprises ten (10) poles (i.e., alternating North and South poles). However it should be appreciated that ring magnet 142 is not limited to only ten (10) poles and may comprise any suitable number of poles. In an exemplary embodiment, ring magnet 142, 146 comprises powder metal or segment assembly. For example, ring magnet 142, 146 may be comprised of individual magnet poles or one solid magnet magnetized with multiple magnet poles.

In an exemplary embodiment, rotor 140 comprises additional ring magnet 146. Sensors 128 are arranged proximate ring magnet 146 to detect motor rotation, as shown in FIG. 10A. For example, sensors 128 may be arranged under ring magnet 146. Ring magnet 146 is non-rotatably connected to ring magnets 142 and 144, for example, via plate 150. In an exemplary embodiment, rotor 140 comprises three ring magnets, namely, ring magnets 142, 144, and 146. Ring magnets 142 and 144 may be stacked and include aligned or alternating poles, as best shown in FIG. 8.

In an exemplary embodiment, rotor 140 further comprises armature or plate 150 non-rotatably connected to ring magnet 142 and/or ring magnet 146. For example, plate 150 may be fixedly secured to ring magnet 144. Plate 150 comprises hole 152 operatively arranged to engage shaft 6. Shaft 6 is non-rotatably connected to plate 150, for example, via splines in hole 152. In an exemplary embodiment, hole 152 is a through-hole. Rotor 140 is operatively arranged to be displaced in circumferential direction CD1, CD2 about axis X, with respect to stator 130 and PCB 122. Axis X extends in axial direction AD1, AD2. Teeth 134 extend in axial direction AD1, the same as axis of rotation X.

FIG. 11 is a bottom perspective view of plate 50, 150. In an exemplary embodiment, as shown, plate 50, 150 comprises surface 54, surface 56, and radially outward facing surface 58. Surface 54 is an axial surface facing generally in axial direction AD2 and operatively arranged to engage ring magnet 42, 142. Surface 56 is an axial surface facing generally in axial direction AD2. Surface 56 is spaced apart from surface 54 in axial direction AD2 and is connected to surface 54 by radially outward facing surface 58. In an exemplary embodiment, plate 50, 150 comprises one or more fins 60 arranged to, when plate 50, 150 is displaced in circumferential direction CD1, CD2, help cool or remove heat from PCB 22, 122. In an exemplary embodiment, fins 60 are arranged on surface 56. In an exemplary embodiment, fins 60 comprise SMC material.

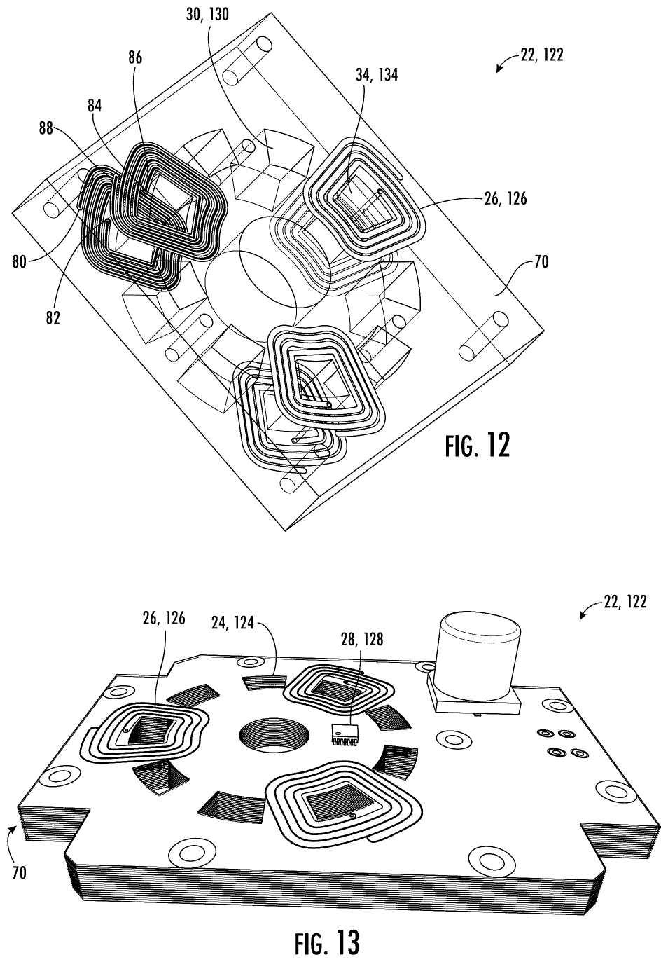

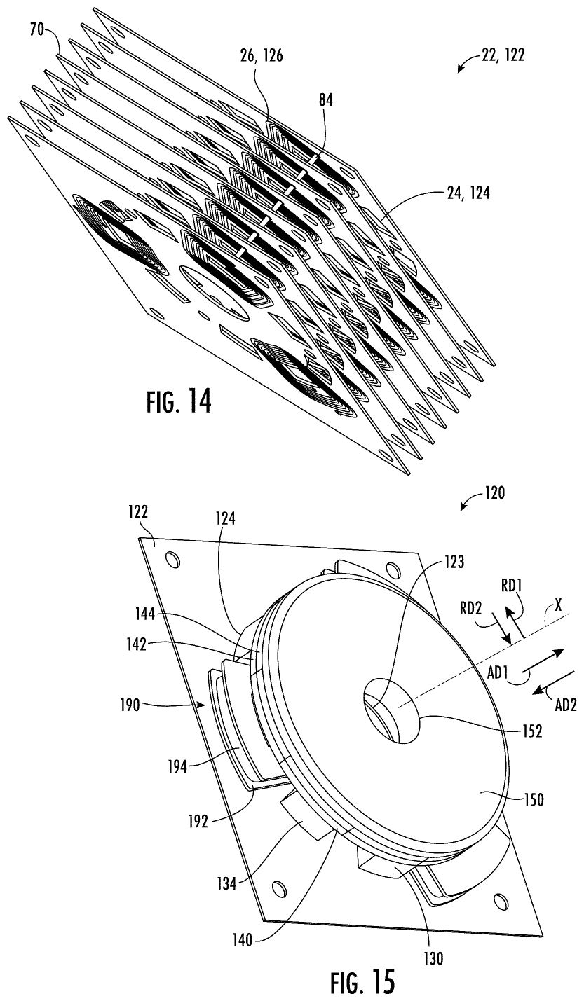

FIG. 12 is a top perspective view of printed circuit board 22, 122. FIG. 13 is a top perspective view of PCB 22, 122. FIG. 14 is an exploded bottom perspective view of PCB 22, 122. In the exemplary embodiment shown, PCB 22, 122 comprises a plurality of layers 70 wherein each layer 70 comprises a plurality of coils 26, 126. Each coil 26, 126 on a layer 70 is electrically connected with each respective circumferentially aligned coil 26, 126 on all other layers 70, for example, via electrical connector 84. In an exemplary embodiment, electrical connector 84 extends in axial direction AD1, AD2. In an exemplary embodiment, electrical connector 84 is a via, for example, a through via or a blind via. Coils 26, 126 are integrated into PCB 22, 122 with each coil arranged on a layer 70 of PCB 22. In an exemplary embodiment, for every layer 70 the turns of coil 26, 126 are additive when appropriately connected.

For example, as best shown in FIGS. 12 and 14, first layer 70 (bottommost layer 70) comprises bottom coil 26, 126 including current entrance 80 and current exit 82. Second layer 70 (topmost layer 70) comprises current entrance 86, electrically connected to current exit 82 through electrical connector 84, and current exit 88. Thus, the current exit of a first layer 70 flows up electrical connector 84 to the next layer 70. The arrangement of coils 26, 126 on multiple layers 70 and in series allows for current to flow in the same direction of rotation on all coils.

FIG. 15 is a top perspective view of electric motor assembly 120. As shown, electric motor assembly 120 may comprise wound coil assembly 190 alternative or in addition to coils 128. Coil assembly 190 may be attached directly to PCB 122 to form a unitary PCB assembly for electric motor assembly 120. Such design reduces the number of layers 70 needed for PCB 122, thereby saving space. Wound coil assemblies 190 are arranged around the respective stator poles and comprise bobbin 192 and coil 194.

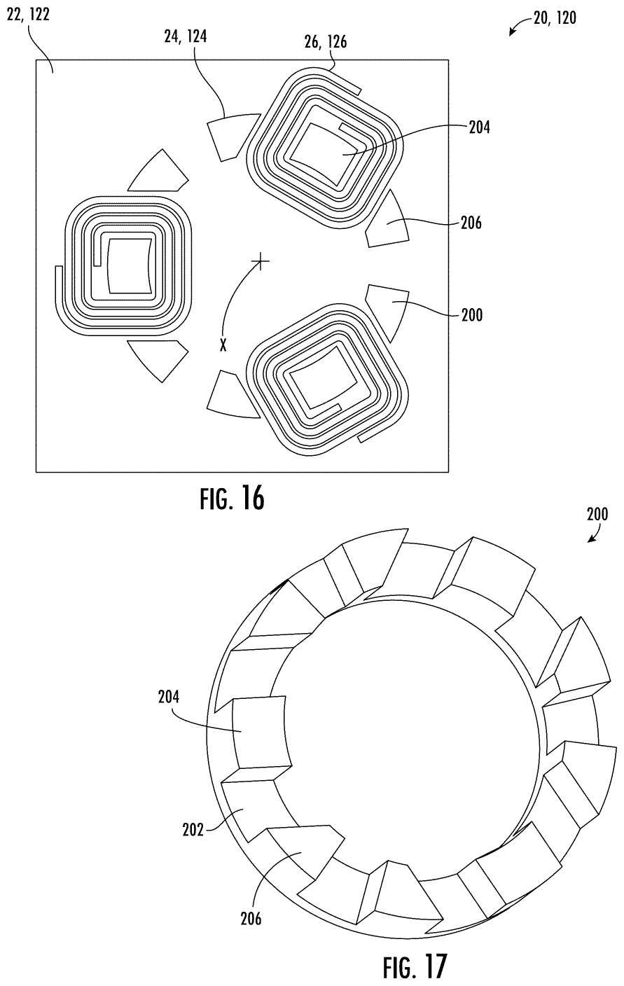

FIG. 16 is a top plan view of electric motor assembly 20, 120 with rotor 40, 140 removed. FIG. 17 is a top perspective view of stator 200. Stator 200 comprises ring portion or yoke 202 and teeth 204, 206 extending axially from ring portion 202, for example in axial direction AD1. As shown, stator poles 204, or stator teeth which are wrapped by coils, are arranged equidistant about ring portion 202. Each of stator poles 204 include opposite surfaces that are parallel to a centerline through the stator pole from axis X. Non-coil stator teeth 206 include surfaces that are parallel to its adjacently arranged corresponding stator pole 206 surface. Stator 200 is arranged to maximize space for coils on PCB 22, 122, as best shown in FIG. 17.

FIG. 18 is a top perspective view of stator 210. Stator 210 comprises ring portion or yoke 212 and teeth 214, 216 extending axially from ring portion 212, for example in axial direction AD1. The radially inward facing surface of stator poles 214 are planar (i.e., flat), whereas the radially inward facing surface of non-coil stator teeth 216 are concave. Stator teeth 216 comprise opposite surfaces that form an angle that is less than 90 degrees. Facing surfaces of adjacently arranged teeth 216 form a triangle shape, and facing surfaces of a tooth 216 and adjacently arranged stator pole 214 form a rectangular shape.

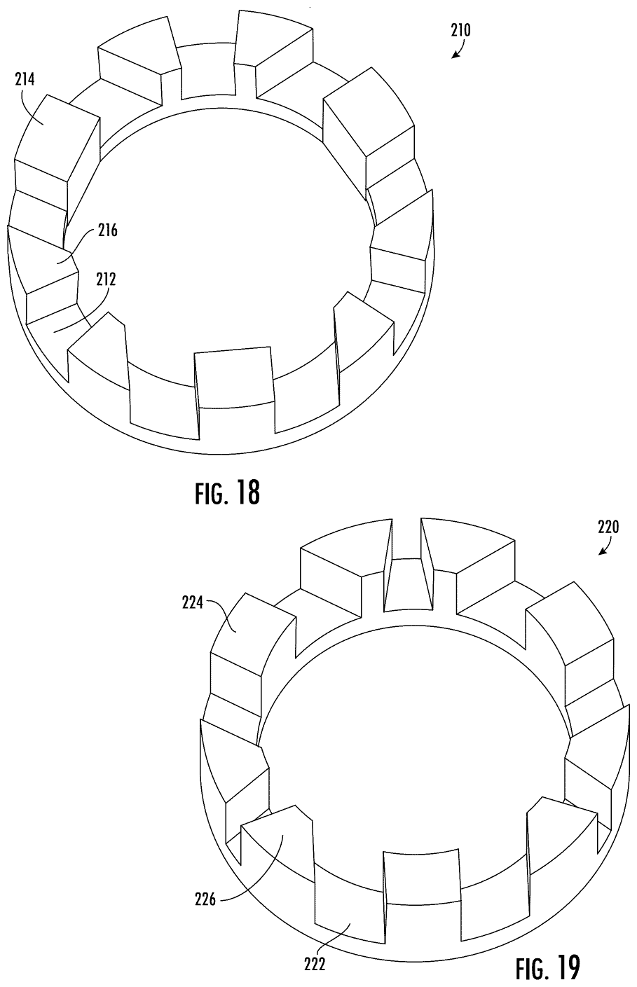

FIG. 19 is a top perspective view of stator 220. Stator 220 comprises ring portion or yoke 222 and teeth 224, 226 extending axially from ring portion 222, for example in axial direction AD1. The arc length of the radially inward facing surface of stator pole 224 is greater than the arc length of the radially inward facing surface of teeth 226. Stator teeth 226 comprise opposite surfaces that form an angle that is less than 90 degrees. Facing surfaces of adjacently arranged teeth 226 form a triangle shape, and facing surfaces of a tooth 226 and adjacently arranged stator pole 224 form a rectangular shape.

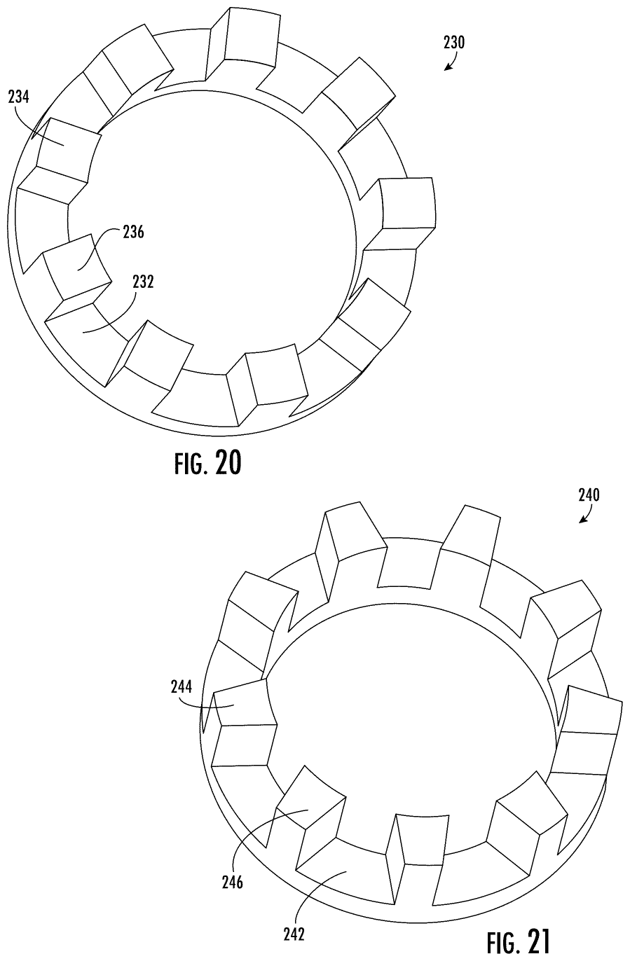

FIG. 20 is a top perspective view of stator 230. Stator 230 comprises ring portion or yoke 232 and teeth 234, 236 extending axially from ring portion 232, for example in axial direction AD1. Stator poles 234 and teeth 236 comprise equal width, sides of teeth 234, 236 are parallel, and teeth 234, 236 have a rectangular shape. In an exemplary embodiment, teeth 234, 236 may have a positive draft angle. The radially inward facing surfaces of teeth 234, 236 are concave and the radially outward facing surfaces of teeth 234, 236 are convex.

FIG. 21 is a top perspective view of stator 240. Stator 240 comprises ring portion or yoke 242 and teeth 244, 246 extending axially from ring portion 242, for example in axial direction AD1. Stator poles 244 and teeth 246 comprise a triangular shape and may have a positive draft angle. The radially inward facing surfaces of teeth 244, 246 are concave and the radially outward facing surfaces of teeth 244, 246 are convex. In an exemplary embodiment, the opposite surfaces of a tooth 244, 246, which face adjacent teeth 244, 246, are concave.

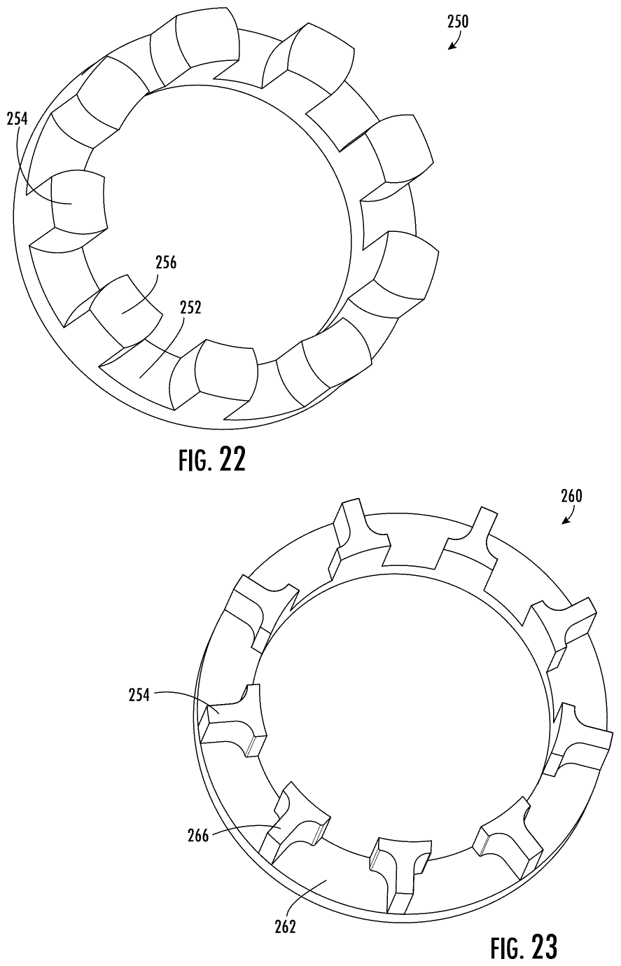

FIG. 22 is a top perspective view of stator 250. Stator 250 comprises ring portion or yoke 252 and teeth 254, 256 extending axially from ring portion 252, for example in axial direction AD1. Stator poles 254 and teeth 256 comprise flat radially inward facing and radially outward facing surfaces, and opposite surfaces of each tooth 254, 256, which face adjacent teeth 254, 256, are convex.

FIG. 23 is a top perspective view of stator 260. Stator 260 comprises ring portion or yoke 262 and teeth 264, 266 extending axially from ring portion 262, for example in axial direction AD1. Teeth 264, 266 are T-shaped, with the radially inward facing surfaces thereof being concave.

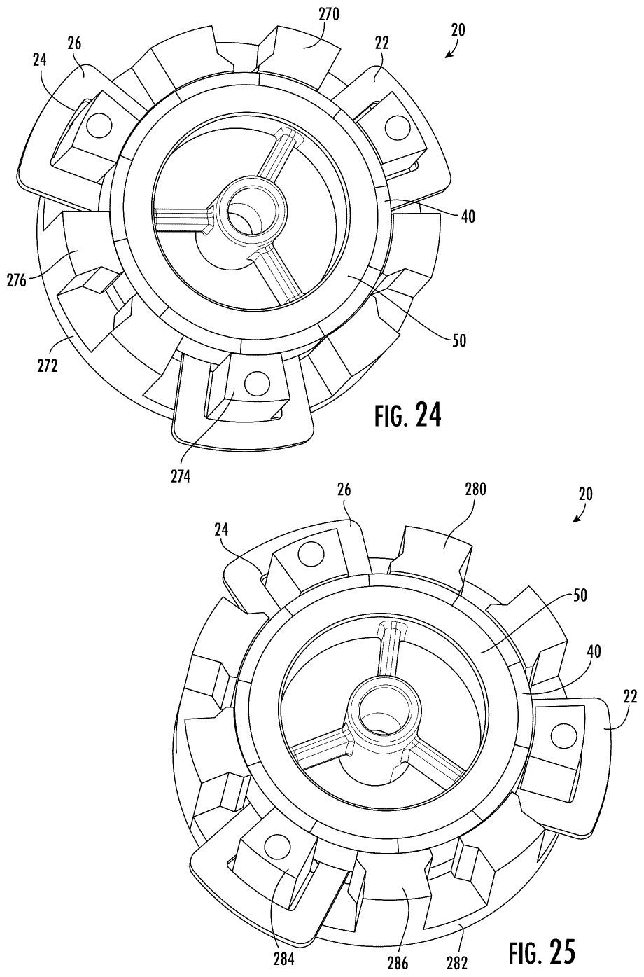

FIG. 24 is a top perspective view of electric motor assembly 20. Stator 270 comprises ring portion or yoke 272 and teeth 274, 276 extending axially from ring portion 272, for example in axial direction AD1. As shown, stator poles 274 comprise through-bores extending axially therethrough in order to secure stator 270. Each tooth 276 comprises a circumferential protrusion that extends toward an adjacent non-coil tooth 276. Such arrangement increases torque output of electric motor assembly 20.

FIG. 25 is a top perspective view of electric motor assembly 20. Stator 280 comprises ring portion or yoke 282 and teeth 284, 286 extending axially from ring portion 282, for example in axial direction AD1. As shown, stator poles 284 comprise through-bores extending axially therethrough in order to secure stator 280. Each tooth 286 comprises two circumferential protrusion, one extending toward an adjacent non-coil tooth 286 and one extending toward a stator pole 284. Such arrangement increases torque output of electric motor assembly 20.

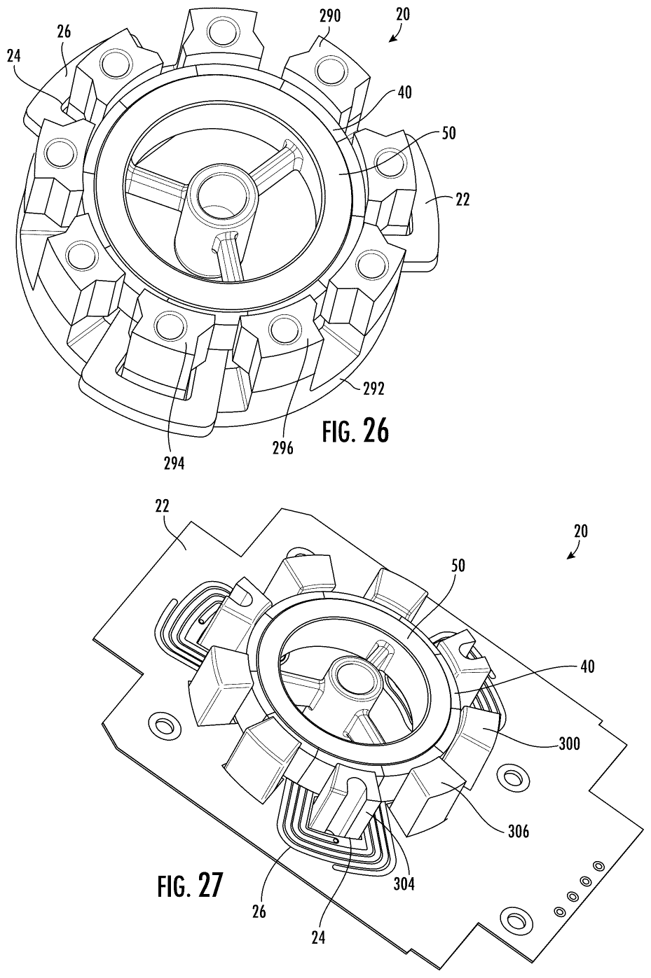

FIG. 26 is a top perspective view of electric motor assembly 20. Stator 290 comprises ring portion or yoke 292 and teeth 294, 296 extending axially from ring portion 292, for example in axial direction AD1. As shown, teeth 294, 296 comprise through-bores extending axially therethrough in order to secure stator 290. Each tooth 294, 296 comprises a sleeve, spaced apart axially, in axial direction AD1, from ring portion 292, that includes two circumferential protrusions, one extending in a first circumferential direction and the other extending in a second circumferential direction. Such arrangement allows for more room for the coils 26 on PCB 22 since the teeth with the shoes are arranged above PCB 22.

FIG. 27 is a top perspective view of electric motor assembly 20. Stator 300 comprises ring portion or yoke 302 and teeth 304, 306 extending axially from ring portion 302, for example in axial direction AD1. As shown, stator poles 304 comprise through-bores extending axially therethrough in order to secure stator 300. In an exemplary embodiment, the through-holes open up to the radially outward facing surface of stator poles 304.

It will be appreciated that various aspects of the disclosure above and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

### REFERENCE NUMERALS

2 Housing
4 Electrical socket
6 Shaft
8 Bearings
10 Actuator assembly
20 Electric motor assembly
22 Printed circuit board
23 Hole
24 Holes
26 Coil
26A Coil
26B Coil
26C Coil
28 Sensor
28A Sensor
28B Sensor
28C Sensor
30 Stator
32 Ring portion or yoke
34 Teeth
36 Radially inward facing surface
40 Rotor
42 Ring magnet
44 Radially inward facing surface
46 Radially outward facing surface
50 Armature or plate
52 Hole
54 Surface
56 Surface
58 Radially outward facing surface
60 Fin
70 Layers
80 Current entrance
82 Current exit
84 Electrical connector or via
86 Current entrance
88 Current exit
120 Electric motor assembly
122 Printed circuit board
123 Hole
124 Holes
126 Coil
128 Sensor
130 Stator
132 Ring portion or yoke
134 Teeth
136 Radially inward facing surface
138 Axial surface
140 Rotor
142 Ring magnet
144 Ring magnet
146 Ring magnet
150 Armature or plate
152 Hole
190 Wound coil assembly
192 Bobbin
194 Coil
200 Stator
202 Ring portion or yoke
204 Stator pole
206 Teeth
210 Stator
212 Ring portion or yoke
214 Stator pole
216 Teeth
220 Stator
222 Ring portion or yoke
224 Stator pole
226 Teeth
230 Stator
232 Ring portion or yoke
234 Stator pole
236 Teeth
240 Stator
242 Ring portion or yoke
244 Stator pole
246 Teeth
250 Stator
252 Ring portion or yoke
254 Stator pole
256 Teeth
260 Stator
262 Ring portion or yoke
264 Stator pole
266 Teeth
270 Stator
272 Ring portion or yoke
274 Stator pole
276 Teeth
280 Stator
282 Ring portion or yoke
284 Stator pole
286 Teeth
290 Stator
292 Ring portion or yoke
294 Stator pole
296 Teeth
300 Stator
302 Ring portion or yoke
304 Stator pole
306 Teeth
AD1 Axial direction
AD2 Axial direction
CD1 Circumferential direction
CD2 Circumferential direction
FP Flux path
RD1 Radial direction
RD2 Radial direction
X Axis

What is claimed is:

1. An electric motor assembly, comprising:
a printed circuit board including a plurality of apertures, wherein at least three apertures of the plurality of apertures are enclosed by coils, the coils being integrated in the printed circuit board;
a stator including a ring portion and a plurality of teeth extending axially from the ring portion, the plurality of teeth extending through the plurality of apertures; and
a rotor arranged adjacent the plurality of teeth, the rotor comprising a first ring magnet;
wherein the coils are arranged to generate a magnetic flux within the stator that is transferred to the rotor to generate circumferential displacement in the rotor about an axis of rotation, and the plurality of teeth extend in an axial direction arranged parallel to the axis of rotation.

2. The electric motor assembly as recited in claim 1, wherein the rotor is arranged axially adjacent to the plurality of teeth and the magnetic flux is transferred axially from the stator to the rotor.

3. The electric motor assembly as recited in claim 1, wherein the rotor is arranged radially adjacent to the plurality of teeth and the magnetic flux is transferred radially from the stator to the rotor.

4. The electric motor assembly as recited in claim 3, wherein the rotor is arranged axially between the ends of the plurality of teeth.

5. The electric motor assembly as recited in claim 1, further comprising a plate non-rotatably connected to the first ring magnet.

6. The electric motor assembly as recited in claim 5, wherein the plate comprises an axial surface including plurality of fins.

7. The electric motor assembly as recited in claim 6, wherein the plurality of fins extend toward that printed circuit board.

8. The electric motor assembly as recited in claim 1, further comprising a Hall effect sensor arranged on the printed circuit board between two coils.

9. The electric motor assembly as recited in claim 6, wherein the Hall effect sensor is arranged radially inward of the plurality of teeth.

10. The electric motor assembly as recited in claim 6, wherein the Hall effect sensor is arranged radially outward of the plurality of teeth.

11. The electric motor assembly as recited in claim 1, wherein the first ring magnet comprises a first radially inward facing surface having a first diameter, the plurality of teeth comprise a second radially inward facing surface having a second diameter, the first diameter being less than the second diameter.

12. The electric motor assembly as recited in claim 1, wherein:
the rotor comprises a radially outward facing surface having a first diameter;
the plurality of teeth comprise a radially inward facing surface having a second diameter; and
the first diameter is greater than the second diameter.

13. The electric motor assembly as recited in claim 1, further comprising a shaft non-rotatably connected to the rotor, the shaft extending through a hole in the printed circuit board.

14. The electric motor assembly as recited in claim 1, further comprising a second ring magnet non-rotatably connected to the first ring magnet.

15. The electric motor assembly as recited in claim 14, wherein the second ring magnet is arranged radially inward and spaced apart from the first ring magnet.

16. The electric motor assembly as recited in claim 1, wherein the printed circuit board comprises a plurality of layers, wherein coils on the plurality of layers are electrically connected with one or more vias.

17. The electric motor assembly as recited in claim 1, wherein:
the ring portion is arranged on a first axial side of the printed circuit board; and
the rotor is arranged on a second axial side of the printed circuit board, opposite the first axial side.

18. The electric motor assembly as recited in claim 1, further comprising a wound coil assembly arranged around at least one of the at least three apertures.

19. The electric motor assembly as recited in claim 1, wherein at least one tooth of the plurality of teeth comprises a through-hole extending therethrough in an axial direction.

20. A brushless direct current motor assembly, comprising:
a printed circuit board including a plurality of apertures, wherein at least three apertures of the plurality of apertures are enclosed by coils, the coils being integrated in the printed circuit board;
a stator including a ring portion and a plurality of teeth extending in an axial direction from the ring portion through the plurality of apertures; and
a rotor arranged adjacent the plurality of teeth, the rotor comprising a first ring magnet;
wherein the coils are arranged to generate a magnetic flux within the stator that is transferred to the rotor to generate circumferential displacement in the rotor about an axis of rotation, wherein the axis of rotation is arranged parallel to the axial direction.
